(19) United States
(12) Patent Application Publication
(10) Pub. No.: US 2002/0092163 A1
(43) Pub. Date: Jul. 18, 2002

(54) Mounting a flexible printed circuit to a heat sink

(76) Inventor: James Fraivillig, Boston, MA (US)

Correspondence Address: ROSENTHAL & OSHA L.L.P., 1221 MCKINNEY AVENUE, SUITE 2800, HOUSTON, TX, 77010, US

(21) Appl. No.: 10/044,604

(22) Filed: Jan. 11, 2002

Related U.S. Application Data
(63) Continuation-in-part of application No. 09/225,272, filed on Jan. 5, 1999.

(51) Int. Cl. H05K 3/02; H05K 3/10; H05K 3/30

(52) U.S. Cl. 29/847; 29/846; 29/832

(57) ABSTRACT

A method for manufacturing a printed circuit bonded to a heat sink includes adhering a conductive layer to a bond film using a first adhesive layer to produce a circuit substrate; processing the circuit substrate to produce a flexible printed circuit; and laminating the heat sink to a second surface of the bond film of the flexible printed circuit using a second adhesive layer. Another method for manufacturing a flexible printed circuit includes placing a release sheet between a first bond film and a second bond film; adhering a first conductive layer to the first bond film to produce a first circuit substrate; adhering a second conductive layer to the second bond film to produce a second circuit substrate; processing the first and the second circuit substrates each to produce a flexible printed circuit; and removing the release sheet. The method may further include laminating the flexible printed circuit to a heat sink.

### CROSS-REFERENCE TO RELATED APPLICATIONS

This is a continuation-in-part of U.S. application Ser. No. 09/225,272, filed on Jan. 5, 1999.

### BACKGROUND OF INVENTION

1. Field of the Invention

The invention relates to mounting a flexible printed circuit to a heat sink.

2. Background Art

A printed circuit may be used as a replacement for wiring when attaching and connecting electrical components in an intricate electrical circuit. A printed circuit is typically smaller and easier to manufacture than a conventional round wire circuit. A typical printed circuit includes an electrically conductive layer (“a conductive layer”), such as a copper foil, that is sandwiched between layers of dielectric insulation. The conductive layer is imaged and etched according to a particular pattern to form a circuit. The imaging and etching process is very accurate, repeatable, and allows the printed circuit to have much higher circuit density than its round wire counterpart.

One type of printed circuit is a printed circuit board (PCB). The PCB uses a flat resin-saturated glass cloth for insulation and protection. The PCB is formed from a conductive layer laminated on such a resin-saturated glass cloth. This conductive layer is imaged and etched to form a circuit pattern. The resin is typically made of a hard and rigid material such as epoxy. Such a board provides the printed circuit with a tough and durable support base.

Another type of printed circuit is a flexible printed circuit, or “flex.” The flexible printed circuit is similar to the PCB except it has a flexible support base, instead of a rigid one. The flexible support base is typically made of a flexible, dielectric material (e.g., a polyimide or polyester film) that allows the printed circuit to be adapted to non-flat structures or to actually “flex” in the application. Typically, the flexible printed circuit includes a conductive layer (e.g., a copper foil) which is laminated to a dielectric layer.

To enhance the dissipation of heat generated by, for example, power semiconductor devices, the flexible printed circuit may be bonded to a thermally conductive heat sink, such as a piece of aluminum or other suitable metal. This heat sink conducts excess heat away from the flexible printed circuit and also provides physical stability to the flexible printed circuit. Because the heat sink is electrically conductive, care must be taken to insulate the conductive layer of the flexible printed circuit from the heat sink. At the same time, it is desirable to maximize the transfer of thermal energy from the conductive layer to the heat sink.

A printed circuit may be adhered to a heat sink in several ways. A circuit substrate may be adhered to a heat sink before the conductive layer is imaged and etched to produce the desired circuit. Alternatively, the conductive layer may be first imaged and etched to produce a printed circuit, followed by adhering the printed circuit to a heat sink. While these prior art methods are sufficient for making a printed circuit and adhering the printed circuit to a heat sink, it is desirable to have more efficient methods for making heat sink backed flexible circuits.

### SUMMARY OF INVENTION

In one aspect, embodiments of the invention relate to methods for manufacturing flexible circuits bonded to heat sinks. A method according to one embodiment of the invention includes adhering a conductive layer to a bond film using a first adhesive layer; processing the conductive layer to produce a printed circuit; and adhering the printed circuit to a heat sink using a second adhesive layer. The processing may include imaging the conductive layer with a circuit pattern; etching the conductive layer to form circuit areas and etched areas, the circuit areas having predefined exposed areas and unexposed areas; coating a protective dielectric material on the etched areas and the predefined unexposed areas on the conductive layer; coating an antioxidant on the predefined exposed areas on the conductive layer. The composition of the first adhesive layer may be different from that of the second adhesive layer.

Another aspect of the invention relates to manufacturing a flexible circuit. A method according to embodiments of the invention includes placing a release sheet between a first bond film and a second bond film; adhering a first conductive layer to the first bond film; adhering a second conductive layer to the second bond film; imaging the first and the second conductive layers each with a circuit pattern; etching the first and the second conductive layers to form circuit areas and etched areas, the circuit areas having predefined exposed areas and unexposed areas; coating a protective dielectric material on the etched areas and the predefined unexposed areas on both the first and the second conductive layers; coating an antioxidant on the predefined exposed areas on both the first and the second conductive layers; and removing the release sheet. The adhering of the conductive layer to the bond film may be achieved in a roll-lamination fashion or a pressed sheet manner. The methods may further include adhering the flexible printed circuit to a heat sink.

Other aspects of the invention will become apparent from the following description, the drawings, and the claims.

### BRIEF DESCRIPTION OF DRAWINGS

FIGS. 1A-1F are schematic diagrams of cross-section views of different embodiments of flexible printed circuits according to the invention and methods for their manufacturing.

FIG. 2 is a schematic diagram showing a back-to-back lamination of two flexible circuits.

FIG. 3 shows cross-section views of a flexible circuit according to one embodiment of the invention after imaging and etching, after coating with a solder mask, and after coating with an antioxidant.

FIG. 4 is a cross-section view of a flexible printed circuit attached to a heat sink according to one embodiment of the invention.

FIG. 5 is a flow chart illustrating a manufacturing process for making a flexible printed circuit and mounting the flexible printed circuit to a heat sink.

### DETAILED DESCRIPTION

Embodiments of the invention relate to flexible printed circuits bonded to heat sinks. According to embodiments of the invention, a flexible printed circuit is bonded to a heat sink using a bond film, which has a dielectric layer sandwiched between a first adhesive layer and a second adhesive layer. The dielectric layer may comprise screen-printed, sprayed, or laminated organic thermosetting coating. The flexible printed circuit is prepared by imaging and etching a conductive layer, which is laminated to bond film using the first adhesive layer. A conductive layer bonded to a bond film will be referred to as a “circuit substrate,” which can be used to produce a printed circuit by imaging and etching the conductive layer. The second adhesive layer may remain B-staged during circuit processing. In these embodiments, the adhesive materials are resistant to the chemicals or conditions used in circuit processing. After circuit processing, the printed circuit is then adhered to the heat sink using the second adhesive layer.

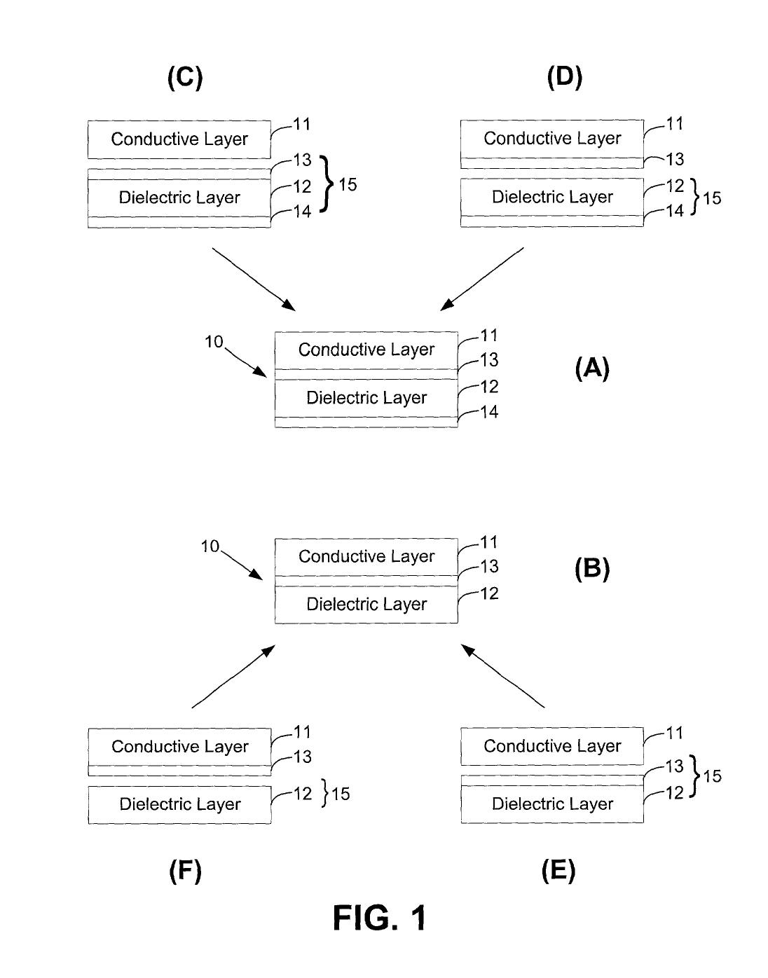

FIGS. 1A-1F illustrate ways to prepare a circuit substrate 10. FIG. 1A and 1B illustrate two different embodiments of flexible circuit substrates 10 that can be used to prepared flexible printed circuits according to embodiments of the invention.

Referring to FIG. 1A, a flexible circuit substrate 10 according to embodiments of the invention may comprise a conductive layer 11 laminated to a dielectric layer 12 by using a first adhesive layer 13. In addition, the dielectric layer may also comprises a second adhesive layer 14, which is adapted to bond a finished circuit to a heat sink. A flexible circuit substrate 10 as shown in FIG. 1A may be prepared, according to FIG. 1C, by laminating a conductive layer 11 to a bond film 15, which comprises a dielectric layer 12 sandwiched between a first adhesive layer 13 and a second adhesive layer 14. Alternatively, a flexible circuit substrate 10 as shown in FIG. 1A may be prepared, according to FIG. 1D, by laminating a conductive layer 11 having a first adhesive layer 13 to a bond film 15, which comprises a dielectric layer 12 sandwiched and a second adhesive layer 14.

FIG. 1B shows another embodiment of a circuit substrate 10, which lacks a second adhesive layer 14 as seen in FIG. 1A. The flexible circuit substrate 10 of FIG. 1B may be prepared, according to FIG. 1E, by laminating a conductive layer 11 to bond film 15 having a dielectric layer 12 and a first adhesive layer 13. Alternatively, the flexible circuit substrate 10 of FIG. 1B may be prepared, according to FIG. 1F, by laminating a conductive layer 12 having a first adhesive layer 13 to a bond film 15 comprising only a dielectric layer 12.

A conductive layer 11 is a thin sheet of metal (a foil) intended for forming a conductive pattern (circuit pattern). Commonly used conductive layers are copper foils. However, other conductive metal or alloy foils may also be used. Copper foils used for printed circuits typically are 15 to 300 microns thick, preferably 19 to 100 microns thick. The thinner the foil, the shorter the required etch time. Thinner foils also permit finer pattern definition. On the other hand, a thicker foil has a higher current-carrying capacity. Thus, the thickness of the conductive layer 11 may be adjusted to suit the desired applications. The conductive layer 11 may have a treatment on one or both sides to facilitate bonding to bond film 15.

According to embodiments of the invention, when the first adhesive layer 13 is activated to adhere the conductive layer 11 to the bond film 15, the second adhesive layer 14, if present, is not activated. The second adhesive layer 14 will be activated when a finished flexible printed circuit is laminated to a heat sink. To achieve such a two-stage lamination, the first adhesive layer 13 and the second adhesive layer 14 may have different compositions. Alternatively, these two adhesive layers may have the same compositions, but the first activation step does not fully activate the adhesive on these two layers; rather, in the first activation step the first adhesive layer 13 is only partially activated to “tack-bond” the conductive layer 11 to the bond film 15. “Tack-bond” as used herein refers to a bonding state in which the bonding strength is sufficient to hold the conductive layer 11 and the bond film 15 together during the circuit manufacturing processes, but the adhesive is not fully activated to form a stronger bond. The adhesives used in printed circuit manufacturing are typically activated by heat and pressure. One can control the conditions of activation (temperature, pressure, and duration) such that a partial bonding occurs (i.e. tack-bond) without fully activating the adhesives.

In embodiments of the invention, the adhesive of the first adhesive layer may be made of materials that can withstand chemical etching during circuit formation and elevated temperatures during thermal bonding of a flexible printed circuit to a heat sink. In addition, the adhesive in the first adhesive layer is preferably thin and thermally-conductive. It can be of a different composition than that of the second adhesive layer. The adhesive of the first adhesive layer may be a material having a lower activation temperature or a thermoset. It can also be B-staged, but needs to hold the copper patterns securely through the circuit making processes. The B-staged adhesive will be fully activated under the conditions used to laminate the flexible printed circuit to a heat sink.

The adhesive of the second adhesive layer preferably has the following properties: (1) the full activation temperature of the adhesive is well in excess of any of the temperature conditions experienced in circuit processing, and (2) any process chemicals do not attack the adhesive or alter its B-staged cure state.

The adhesive material may be, for example, a polyimide, acrylic, or epoxy film. The adhesive layer (film), in some embodiments, has a thickness of 3 to 25 microns. It may be desirable to have different compositions of the adhesive materials on the two adhesive layers so that one can better control the two-step activation process and optimize bond strengths to etched conductors and the heat sink.

In addition, the thickness of the adhesives which form the adhesive layers 13 and 14 can be chosen based on the intended application of the circuit. Thinner adhesive layers have better thermal transfer than thicker layers. In some embodiments, a high-temperature resistant adhesive such as an epoxy or acrylic or polyimide is used. Also, in some embodiments, the adhesive layer 13 may include a thermoplastic adhesive that has a fast bonding time for bonding the conductive layer 11 to the dielectric layer 12.

The bond film 15 according to embodiments of the invention may comprise only the dielectric layer 12, or it may also comprise the first adhesive layer 13. In the embodiments in which the bond film 15 comprises only the dielectric layer 12, the conductive layer 11 may comprise the first adhesive layer 13. In other embodiments, the bond film 15 may comprise a dielectric layer 12, a first adhesive layer 13, and a second adhesive layer 14. In the embodiments in which the bond film 15 does not comprise a second adhesive layer 14, the second adhesive layer 14 may be put on the bond film 15 at any time after the bond film 15 has been laminated to the conductive layer 11, but before the finished flexible circuit is to be laminated to a heat sink. Alternatively, the second adhesive layer 14 may be put on the heat sink before it is to be laminated to a finished flexible circuit.

In the embodiments of the invention, the dielectric layer 12, the first adhesive layer 13, and the second adhesive layer 14 are preferably comprised of thermally-conductive materials. The dielectric layer 12 may be a polyimide film or a polyester (polyethylene naphthalate, PEN) film. Alternatively, the dielectric layer 12 may be a ceramic-filled polyimide film such as one sold under the trade name Kapton™MT by E. I. du Pont de Nemours and Company, Wilmington, Del. The thickness of the dielectric layer 12 may be about 8 to 75 microns, preferably about 12 to 50 microns.

The adhesive layers 13 and 14, in some embodiments, may include a high-temperature thermoplastic adhesive such as a polyimide, polyamide, or polyester adhesive. In other embodiments, the adhesive layers 13 and 14 may include a modified polyimide adhesive that is thermally-conductive. The thickness of the adhesive layers 13 and 14 may be about 2 to 12 microns per layer, preferably about 3 to 7 microns. The first adhesive layer 13 may comprise a material which requires a relatively moderate bonding temperature and pressure for relatively fast bonding. The first adhesive layer 13 may provide a strong, robust bond between the conductive layer 11 and the bond film 15 over a wide range of environmental stresses, for example, during etching of the conductive layer 11 and laminating the flexible circuit to a heat sink 16 (see FIG. 4).

The second adhesive layer 14, in some embodiments (see FIG. 1A), will retain its “bondability” throughout the various steps required to make the circuit. “Bondability” means the ability to unite materials by adhesion. The second adhesive layer 14 may remain B-staged during the processes of laminating the conductive layer 11 to the bond film 15, printing and etching, and coating the circuitry. B-stage is an intermediate stage of cure in the reaction of certain thermosetting or thermally-cured thermoplastic resins in which the material softens when heated and can bond with adjacent surfaces. In some embodiments, the adhesive of the second adhesive layer 14 may have a full activation temperature higher than any of the temperature conditions experienced in circuit processing, and it is not attacked or reacted by the process chemicals and conditions so that it remains at its B-staged cure status.

As explained earlier, the adhesive of the first adhesive layer 13 may be of a different composition from that of the second adhesive layer 14. The adhesive of the first adhesive layer 13 may have a lower activation temperature and/or be a thermoset. It may also be B-staged (as it also sees the final lamination temperature used to laminate the circuit to the heat sink 16), but needs to hold the circuit pattern in the conductive layer 11 securely through the circuit processes. It may permit a continuous roll-lamination of the conductive layer 11 to the bond film 15 before circuit processing. Roll-lamination (i.e., lamination in a rolling fashion), in which the conductive layer 11 and/or bond film 15 is present in a roll form, saves handling and processing costs.

In a roll-lamination, a sheet or roll of bond film 15 is laminated to a sheet or roll of the conductive layer 11. The lamination is achieved with the first adhesive layer 13, which may be on the conductive layer 11 or on the bond film 15.

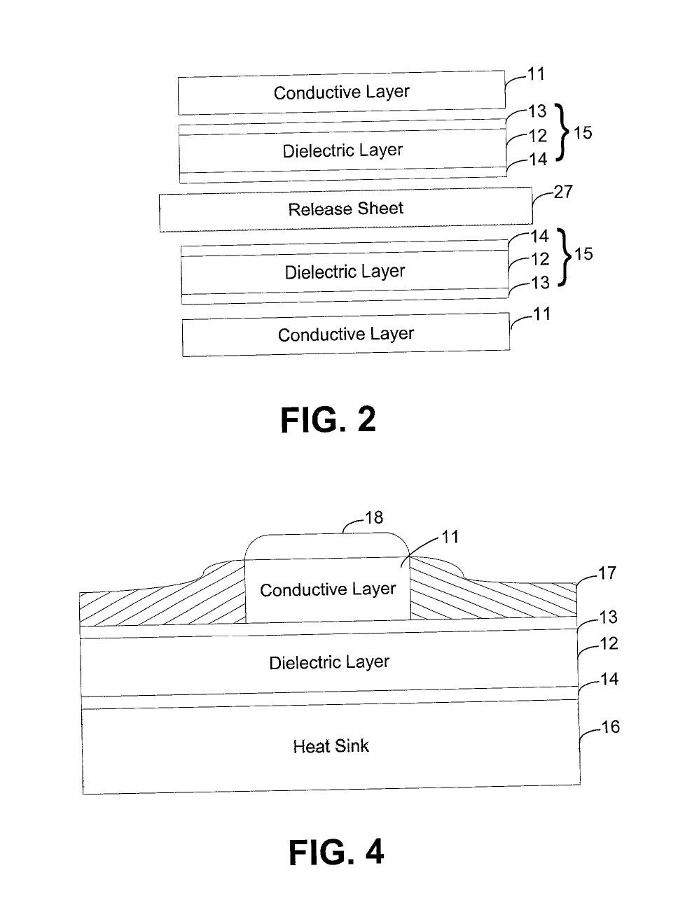

Alternatively, the lamination may be performed in sheet form. That is, both the conductive layer and the bond film are in sheet forms. Lamination using sheet forms of the conductive layer and bond film will be referred to as lamination in a pressed sheet manner. Furthermore, the lamination, whether in sheet form or in roll form, may be conducted in a fashion, as shown in FIG. 2, in which two flexible circuit substrates may be produced at the same time. In this approach, a release sheet 27 is placed between two bond films 15 in such an orientation that the first adhesive layer 13 on each bond film faces away from the release sheet 27. One conductive layer 11 each is then laminated to the bond film 15 by using the adhesive layer 13 (see FIG. 2). The release sheet 27 may be a material such as that sold under the trade name Teflon™ film and Teflon™-coated glass cloth by E. I. du Pont de Nemours and Company, Wilmington, Del., or any suitable material which will not bond to the second adhesive layer 14 under the conditions used in the first lamination step. The release sheet 27 may be removed after laminating the conductive layer 11 to the bond film 15, or after the circuit panel has been processed. It should be noted that this dual lamination (or back-to-back lamination) process, as shown in FIG. 2, may be employed whether the lamination is performed in sheet form or in roll form.

In the first lamination (adhering) step, the bond film 15 may be tack-bonded to the conductive layer 11. The temperature for this lamination is well below the optimal bond temperature. For the thermoplastic polyimide adhesive may be tack-bonded at a temperature of about 160-1900° C., while the optimal bond temperature is about 220-300° C. A typical lamination condition may involve a temperature of about 100-180° C., and a pressure of about 50-1000 psi, for a duration of about 1-180 seconds. The lower bond temperature allows further reactivity in the adhesive (the second adhesive layer 14) for later lamination to a heat sink at the optimal, higher bond temperature. The tack-bond lamination—the conductive layer 11 plus the bond film 15—must still survive the circuit etching, solder mask, and unitizing processes. This tack-bonding may be performed in a traditional lamination, roll lamination, or dual lamination (as shown in FIG. 2) process.

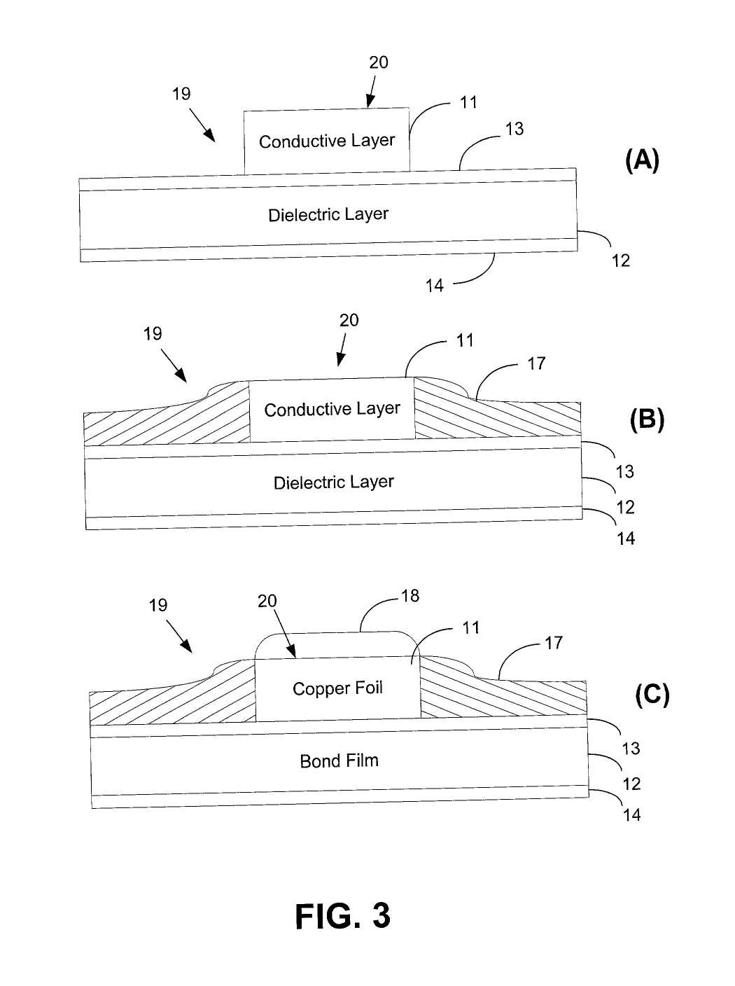

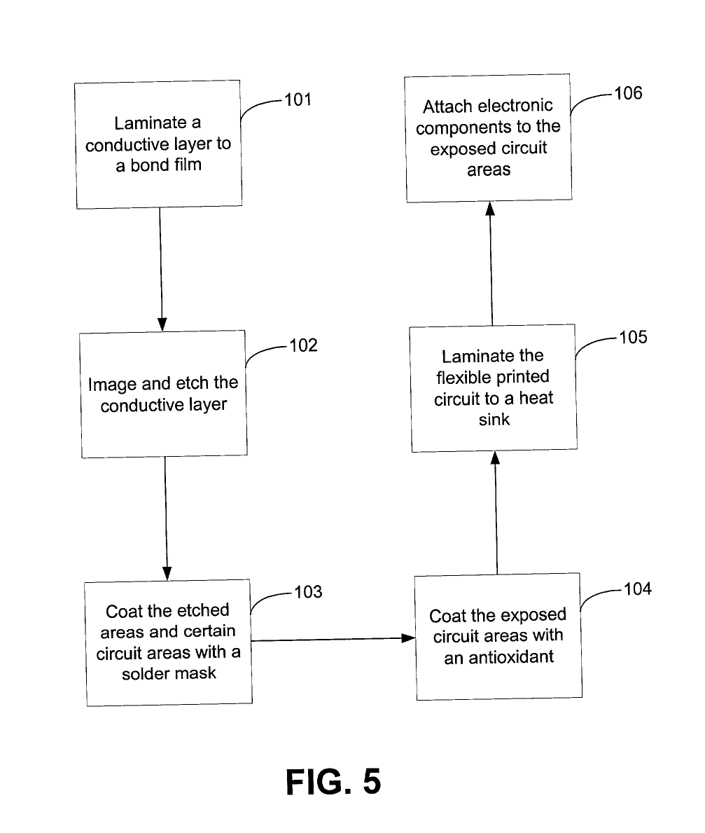

FIG. 5 summarizes the process. First, a conductive layer 11 is laminated to a bond film 15 (101 in FIG. 5). A flexible circuit substrate 10 thus formed can then be further processed to produce a desired circuit. The circuit patterns may be imaged and etched on the conductive layer 11 (102 in FIG. 5). FIG. 3A shows a cross-section view of an imaged and etched circuit. The imaging and etching produce the “etched areas” 19 and the “circuit areas” 20 on the conductive layer 11 (FIG. 3A). The bond film, which may include the first adhesive layer 13, the dielectric layer 12, and the second adhesive layer 14, is not affected by the imaging and etching processes.

After imaging and etching, a solder mask layer 17, which is a dielectric layer and a guard against later solder addition to the conductive pattern areas, may be added to the “etched areas” 19 and certain “circuit areas” 20 that are not to be connected to any electronic component (predefined unexposed circuit areas) (103 in FIG. 5). The material used for the solder mask is referred to as a protective dielectric material. FIG. 3B shows a cross-section view of a flexible circuit after a solder mask layer has been coated on the “etched areas” 19. It should be noted that this particular view does not show a solder mask coating on any part of the “circuit areas.” In some embodiments of the invention, certain part of the “circuit areas” (predefined unexposed circuit areas) may also be coated with a solder mask.

Next, a solderability protection coating (an antioxidant layer) 18 may be added to the predefined exposed “circuit areas” 20 on the conductive layer 11 to prevent oxidation and to facilitate the soldering of electronic components (not shown) during board assembly (104 in FIG. 5). The predefined exposed circuit areas are those circuit areas that are for attachment of electronic components and are not coated with the solder mask. The antioxidant coating may be a polymer (organic antioxidant) coating or metal plating, such as tin/lead, gold, etc.

If the initial lamination (101 in FIG. 5) is performed in a dual lamination mode as illustrated in FIG. 2, then the finished circuit patterns may be separated from the release sheet 27 at this stage. Alternatively, the release sheet 27 may be removed earlier and the flexible circuit substrates processed separately. For process economy, it is desirable to remove the release sheet 27 after antioxidant coating (104 in FIG. 5) so that two circuits may be processed at the same time up to this point. Removal of the release sheet 27 re-exposes the second adhesive layer 14, making it available to laminate to a heat sink. If multiple circuits have been processed on one panel of flexible circuit substrate 10 (see FIG. 1A or 1B), the individual circuits may then be de-panelized before or after the removal of the release sheet 27. Depanelization is typically performed with a steel-ruled die press.

Referring to FIG. 4, then, an individual circuit is placed on a heat sink 16 and laminated with high heat (e.g., about 220-300° C.) and high pressure (e.g., about 50-1000 psi) (105 in FIG. 5). The lamination may be achieved in about 10 seconds to about 10 minutes. To facilitate the final lamination, the heat sink may be pre-primed with a very thin layer (about 1-3 micron, dry) of the same adhesive as that of the second adhesive layer 14. The pre-priming eliminates concerns of surface contamination, which degrades bond strength. In addition, pre-priming also reduces bond temperature, because “like” surface compositions are mated. FIG. 4 illustrates a cross-section view of a flexible printed circuit having a heat sink 16 according to embodiments of the invention.

At this stage, the manufacturing of a flexible printed circuit is complete. The finished circuitry can be used for attachment of other electronic components by soldering (106 in FIG. 5). Heat generated by their operation in use is dissipated to the heat sink 16, through the bond film 15. Thermal transfer between the electronic components and the heat sink is very high, because they are separated by a thin, thermally-conductive bond film 15.

In addition to dissipating heat, heat sink 16 provides structural support for bond film 15. Furthermore, heat sink 16 also provides electrical shielding for flexible printed circuit 10, because heat sink 16 may reduce the reception and/or transmission of electromagnetic interference (EMI).

While the invention has been described with respect to a limited number of embodiments, those skilled in the art, having benefit of this disclosure, will appreciate that other embodiments can be devised which do not depart from the scope of the invention as disclosed herein. For example, the invention is equally applicable to heat sinks having various shapes and is not limited to heat sinks in the shapes shown. Also, a flexible printed circuit comprising multiple conductive layers instead of a single layer may be used. Furthermore, multiple flexible printed circuits may be manufactured on a single sheet, then individual circuits may be punched out as needed. Accordingly, the scope of the invention should be limited only by the attached claims.

What is claimed is:

1. A method for manufacturing a printed circuit bonded to a heat sink comprising:
adhering a conductive layer to a first surface of a bond film using a first adhesive layer to produce a circuit substrate, wherein the adhering is achieved by partially activating the first adhesive layer such that the conductive layer is tack-bonded to the bond film;
processing the circuit substrate to produce a flexible printed circuit; and
laminating the heat sink to a second surface of the bond film of the flexible printed circuit using a second adhesive layer.

2. The method of claim 1, wherein the adhering of the conductive layer to the first surface of the bond film is performed in a temperature range of from about 100 to about 180 degrees Celsius and a pressure range of from about 50 to about 1000 pounds per square inch.

3. The method of claim 1, wherein the laminating of the heat sink to the second surface of the bond film is performed in a temperature range of from about 220 to about 300 degrees Celsius and a pressure range of from about 50 to about 1000 pounds per square inch.

4. The method of claim 1, wherein a composition of the first adhesive layer is different from a composition of the second adhesive layer.

5. The method of claim 4, wherein the compositions are selected to have different bonding temperatures.

6. The method of claim 1, wherein the processing comprises
imaging the conductive layer with a circuit pattern;
etching the imaged conductive layer to form circuit areas and etched areas, the circuit areas having predefined exposed areas and unexposed areas;
coating the etched areas and the predefined unexposed circuit areas with a protective dielectric material; and
coating the predefined exposed circuit areas with an antioxidant layer to produce the flexible printed circuit.

7. The method of claim 6, wherein the antioxidant layer comprises one selected from a polymer coating and a metal plating.

8. The method of claim 1, wherein the conductive layer comprises a copper foil.

9. The method of claim 1, wherein the adhering is performed in a pressed sheet manner.

10. The method of claim 1, wherein the adhering is performed in a roll-lamination fashion.

11. The method of claim 1, wherein the first adhesive layer is coated on the first surface of the bond film prior to the adhering.

12. The method of claim 1, wherein the first adhesive layer is coated on the conductive layer prior to the adhering.

13. The method of claim 1, wherein the second adhesive layer was coated on the second surface of the bond film prior to the adhering of the conductive layer to the first surface of the bond film.

14. The method of claim 1, wherein the second adhesive layer was coated on the second surface of the bond film after the adhering of the conductive layer to the first surface of the bond film, and prior to the laminating the heat sink to the second surface of the bond film.

15. The method of claim 1, wherein the second adhesive layer is coated on the heat sink prior to the laminating the heat sink to the second surface of the bond film.

16. A method for manufacturing a printed circuit bonded to a heat sink comprising:
adhering a conductive layer to a first surface of a bond film using a first adhesive layer to produce a circuit substrate;
processing the circuit substrate to produce a flexible printed circuit; and
laminating the heat sink to a second surface of the bond film of the flexible printed circuit using a second adhesive layer,
wherein a composition of the first adhesive layer is different from a composition of the second adhesive layer such that the second adhesive layer is not fully activated at a temperature used in the adhering the conductive layer to the bond film.

17. A method for manufacturing a flexible printed circuit comprising:
placing a release sheet between a first bond film and a second bond film;
adhering a first conductive layer to a first surface of the first bond film to produce a first circuit substrate, the adhering is performed such that the first conductive layer is tack-bonded to the first bond film;
adhering a second conductive layer to a first surface of the second bond film to produce a second circuit substrate, the adhering is performed such that the second conductive layer is tack-bonded to the second bond film; and
removing the release sheet.

18. The method of claim 17, wherein the adhering the first conductive layer to the first bond film and the adhering the second conductive layer to the second bond film are performed in a temperature range of from about 100 to about 180 degrees Celsius and a pressure range of from about 50 to about 1000 pounds per square inch.

19. The method of claim 17, wherein the adhering the first conductive layer to the first surface of the first bond film is by using an adhesive layer coated on the first surface of the first bond film prior to the adhering.

20. The method of claim 17, wherein the adhering the first conductive layer to the first surface of the first bond film is by using an adhesive layer coated on the first conductive layer prior to the adhering.

21. The method of claim 17, wherein the adhering the second conductive layer to the first surface of the second bond film is by using an adhesive layer coated on the first surface of the second bond film prior to the adhering.

22. The method of claim 17, wherein the adhering the second conductive layer to the first surface of the second bond film is by using an adhesive layer coated on the second conductive layer prior to the adhering.

23. The method of claim 17, wherein the adhering the first conductive layer to the first bond film and the adhering the second conductive layer to the second bond film are performed in a roll-lamination fashion.

24. The method of claim 17, wherein the adhering the first conductive layer to the first bond film and the adhering the second conductive layer to the second bond film are performed in a pressed sheet manner.

25. The method of claim 17, further comprising processing the first and the second circuit substrates each to produce a flexible printed circuit.

26. The method of claim 25, wherein the processing is performed prior to the removing the release sheet.

27. The method of claim 25, wherein the processing comprises imaging the first and the second conductive layers each with a circuit pattern;
etching the first and the second conductive layers each to form circuit areas and etched areas, the circuit areas having predefined exposed areas and unexposed areas;
coating a protective dielectric material on the etched areas and the predefined unexposed areas on both the first and the second conductive layers; and
coating an antioxidant on the predefined exposed areas on both the first and the second conductive layers.

28. The method of claim 25, further comprising laminating each of the flexible printed circuits to a heat sink.

29. The method of claim 28, wherein the laminating of the heat sink to the second surface of the bond film is performed in a temperature range of from about 220 to about 300 degrees Celsius and a pressure range of from about 50 to about 1000 pounds per square inch.
